(19) United States
(12) Patent Application Publication
(10) Pub. No.: US 2025/0338569 A1
(43) Pub. Date: Oct. 30, 2025

(54) SEMICONDUCTOR DEVICE AND METHOD OF MANUFACTURING THE SAME

(71) Applicant: Renesas Electronics Corporation, Tokyo (JP)

(72) Inventor: Kazuya KAMON, Tokyo (JP)

(21) Appl. No.: 19/171,417

(22) Filed: Apr. 7, 2025

(30) Foreign Application Priority Data
Apr. 24, 2024 (JP) 2024-070636

(51) Int. Cl. H10D 62/10; H01L 21/762; H10D 30/60; H10D 62/40; H10D 64/27

(52) U.S. Cl. CPC H10D 62/102; H01L 21/76224; H10D 62/40; H10D 64/514; H10D 30/601; H10D 62/113

(57) ABSTRACT

A semiconductor device includes a semiconductor substrate including a single crystal layer, a plurality of semiconductor elements formed on the single crystal layer, and an isolation film which is formed in the semiconductor substrate so as to surround each of the plurality of semiconductor elements in plan view and isolates the plurality of semiconductor elements from one another. The isolation film is made of an antiferroelectric. A minimum value of a relative dielectric constant of the isolation film is less than 2.

### CROSS-REFERENCE TO RELATED APPLICATIONS

The disclosure of Japanese Patent Application No. 2024-070636 filed on Apr. 24, 2024 including the specification, drawings and abstract is incorporated herein by reference in its entirety.

### BACKGROUND

This disclosure relates to a semiconductor device and a method of manufacturing the same.

There are disclosed techniques listed below.
[Patent Document 1] Japanese Unexamined Patent Application Publication No. 2013-222838
[Patent Document 2] Japanese Unexamined Patent Application Publication No. 2002-313906

Conventionally, a semiconductor device having an element isolation film for electrically isolating a plurality of semiconductor elements formed on a semiconductor substrate from one another has been known (see, for example, Patent Document 1).

Also, a semiconductor device provided with an SOI (Silicon On Insulator) substrate having a buried insulating film and a transistor formed on a semiconductor layer of the SOI substrate has been known (see, for example, Patent Document 2).

### SUMMARY

In recent years, with the increase in operation speed of semiconductor devices, there is a demand for reducing the capacitance of isolation films such as an element isolation film and a buried insulating film, and research has been conducted on a material with a relative dielectric constant lower than that of a silicon oxide film as the material configuring the isolation film.

However, when the material with a relative dielectric constant lower than that of a silicon oxide film is adopted as the isolation film, it is more difficult to suppress the occurrence of soft errors as compared with the case in which the isolation film is made of a silicon oxide film.

Other problems and novel features will be apparent from the description of this specification and accompanying drawings.

A semiconductor device according to one embodiment includes a semiconductor substrate including a single crystal layer, a plurality of semiconductor elements formed on the single crystal layer, and an isolation film which is formed in the semiconductor substrate so as to surround each of the plurality of semiconductor elements in plan view and isolates the plurality of semiconductor elements from one another. The isolation film is made of an antiferroelectric. A minimum value of a relative dielectric constant of the isolation film is less than 2.

A semiconductor device according to another embodiment includes a semiconductor substrate including a bulk layer and a single crystal layer and a plurality of semiconductor elements formed on the single crystal layer. The semiconductor substrate further includes an isolation film which is arranged between the bulk layer and the single crystal layer and isolates the bulk layer and the plurality of semiconductor elements from each other. The isolation film is made of an antiferroelectric. A minimum value of a relative dielectric constant of the isolation film is less than 2.

A method of manufacturing a semiconductor device according to one embodiment includes a first step of preparing a semiconductor substrate including a single crystal layer, a second step of forming a plurality of semiconductor elements on the single crystal layer, and a third step of forming in the single crystal layer an isolation film which isolates the plurality of semiconductor elements from one another. In the third step, the isolation film made of an antiferroelectric is formed by heating to a temperature lower than a Curie point of the antiferroelectric so as to surround each of the plurality of semiconductor elements in plan view.

A method of manufacturing a semiconductor device according to another embodiment includes a first step of preparing a semiconductor substrate including a bulk layer, a single crystal layer, and an isolation film which is arranged between the bulk layer and the single crystal layer and isolates the bulk layer and the single crystal layer from each other and a second step of forming a plurality of semiconductor elements on the single crystal layer. In the first step, the isolation film made of an antiferroelectric is formed by heating to a temperature lower than a Curie point of the antiferroelectric.

According to this disclosure, it is possible to provide a semiconductor device capable of suppressing the occurrence of soft errors as compared with the case in which the isolation film is made of a silicon oxide film.

### BRIEF DESCRIPTION OF THE DRAWINGS

FIG. 1 is a plan view illustrating a configuration example of a semiconductor device according to a first embodiment.

FIG. 2 is a partially enlarged plan view illustrating a configuration example of a semiconductor element included in the semiconductor device according to the first embodiment.

FIG. 3 is a cross-sectional view of the semiconductor element illustrated in FIG. 2.

FIG. 4 is a graph illustrating a relationship between an electric field and polarization of an antiferroelectric obtained by simulation.

FIG. 5 is a graph illustrating a relationship between an electric field and a relative dielectric constant of an antiferroelectric obtained by simulation.

FIG. 6 is a flowchart illustrating an example of a method of manufacturing a semiconductor device according to the first embodiment.

FIG. 7 partially enlarged cross-sectional view illustrating a configuration example of a semiconductor element included in a semiconductor device according to a second embodiment.

FIG. 8 is a flowchart illustrating an example of a method of manufacturing a semiconductor device according to the second embodiment.

FIG. 9 is a partially enlarged cross-sectional view illustrating a configuration example of a semiconductor element included in a semiconductor device according to a third embodiment.

FIG. 10 is a circuit diagram illustrating an example of a circuit realized when ESD pulse enters the semiconductor device according to the third embodiment.

FIG. 11 is a graph illustrating a temporal change of current flowing through a MOS transistor after the ESD pulse enters the semiconductor device according to the third embodiment.

FIG. 12 is a partially enlarged cross-sectional view illustrating a configuration example of a semiconductor element included in a modification of the semiconductor device according to the third embodiment.

FIG. 13 is a circuit diagram illustrating an example of a circuit realized when ESD pulse enters the modification of the semiconductor device according to the third embodiment.

### DETAILED DESCRIPTION

Hereinafter, embodiments will be described with reference to drawings. Note that the same or corresponding components are denoted by the same reference characters in the following drawings, and the descriptions thereof will not be repeated.

### First Embodiment

### Configuration of Semiconductor Device

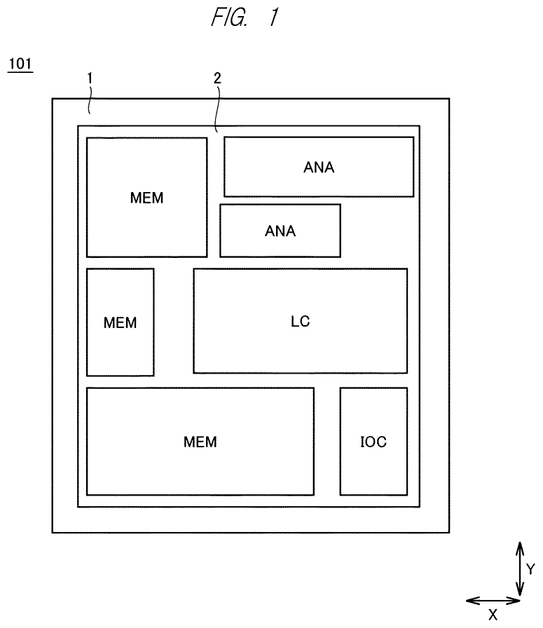

FIG. 1 is a plan view of a semiconductor device 101 according to the first embodiment. As illustrated in FIG. 1, the semiconductor device 101 according to the first embodiment includes a scribe region 1 and a module region 2. The scribe region 1 has an outer peripheral edge of the semiconductor device 101 formed by a scribing process to a semiconductor substrate. The module region 2 is formed inside the scribe region 1 in plan view. The module region 2 includes, for example, an input/output circuit IOC, an analog circuit ANA, a logic circuit LC, a memory circuit MEM, and others. The memory circuit MEM includes a plurality of memory cells.

The module region 2 includes a plurality of semiconductor elements. The plurality of semiconductor elements includes at least transistors or diodes. The plurality of semiconductor elements includes, for example, vertical insulated gate field effect transistors. The insulated gate field effect transistor is, for example, a MIS (Metal Insulator Semiconductor) transistor. The MIS (Metal Insulator Semiconductor) transistor is, for example, a MOS (Metal Oxide Semiconductor) transistor. For example, the MOS transistor is included in each of the plurality of memory cells in the memory circuit MEM. Note that the semiconductor elements included in the module region 2 are not particularly limited.

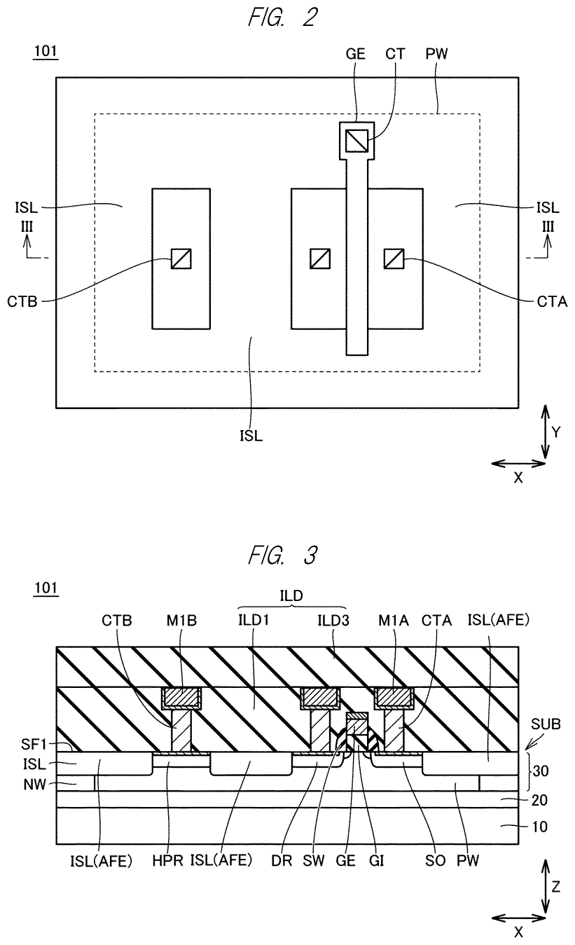

FIG. 2 is a partially enlarged plan view illustrating a MOS transistor included in one memory cell in the semiconductor device 101. FIG. 3 is a cross-sectional view taken along the arrow III-III in FIG. 2. As illustrated in FIG. 2, the semiconductor device 101 is formed using a semiconductor substrate SUB. The semiconductor substrate SUB has a first surface SF1. A MOS transistor TR is formed on the first surface SF1.

In this specification, two directions perpendicular to each other along the first surface SF1 are referred to as the X direction and the Y direction. A direction perpendicular to the first surface SF1 is referred to as the Z direction. In the Z direction, a direction from a single crystal layer 30 toward a bulk layer 10 is referred to as the downward direction, and a direction from the bulk layer 10 toward the single crystal layer 30 is referred to as the upward direction. A viewpoint viewing from above in the Z direction is referred to as a plan view.

The semiconductor substrate SUB is, for example, an SOI (Silicon On Insulator) substrate. The SOI substrate has the bulk layer 10, a substrate isolation film 20, and the single crystal layer 30. The bulk layer 10, the substrate isolation film 20, and the single crystal layer 30 are stacked in the Z direction in this order. The substrate isolation film 20 is arranged between the bulk layer 10 and the single crystal layer 30. The material configuring the bulk layer 10 is, for example, P-type single crystal silicon. The substrate isolation film 20 is, for example, a buried oxide (BOX) film. The material configuring the substrate isolation film 20 is, for example, an n-type silicon oxide film. The material configuring the single crystal layer 30 is, for example, single crystal silicon. The single crystal layer 30 has, for example, a p-type well PW, a source SO and a drain DR which are n-type impurity regions, and a channel region between the source SO and the drain DR. Note that the semiconductor substrate SUB of the semiconductor device 101 is not limited to an SOI substrate.

The MOS transistor TR1 is, for example, an NMOS (N-channel MOS) transistor. The MOS transistor TR1 includes the p-type well PW, the source SO and the drain DR which are n-type impurity regions, the channel region between the source SO and the drain DR, and a gate electrode GE. The p-type well PW, the source SO and the drain DR, and the channel region are formed in the single crystal layer 30. The drain DR, the source SO, and the channel region are formed in an upper part of the p-type well PW. The source SO and the drain DR are arranged with an interval in the X direction. The gate electrode GE is formed on the channel region via a gate insulating film GI. A sidewall insulating film SW is formed on the side walls of the gate insulating film GI and the gate electrode GE. The sidewall insulating film SW includes, for example, at least one of a silicon oxide film and a silicon nitride film. Each of the source SO and the drain DR is connected to a plurality of first wiring layers M1A to be described later via a first contact CT layer C1A. Each of the source SO and the drain DR may have an LDD (Lightly Doped Drain) structure. Note that the MOS transistor TR1 may be a PMOS (P-channel MOS) transistor.

The semiconductor device 101 further includes a contact element for fixing the potential of the p-type well PW in addition to the MOS transistor TR. For example, the contact element is arranged side by side with the MOS transistor TR in the X direction. The contact element includes, for example, a p-type impurity region HPR and a second contact CTB. The p-type impurity region HPR is formed in an upper part of the p-type well PW. The second contact CTB is connected to the p-type impurity region HPR. For example, the second contact CTB is arranged with an interval from the first contact CTA in the X direction.

The semiconductor device 101 further includes an element isolation film ISL. The element isolation film ISL is formed, for example, between the MOS transistors TR adjacent in the X-direction or Y-direction and between the MOS transistor TR and the contact CT element. The element isolation film ISL is arranged so as to surround each of the MOS transistors TR and the contact CT elements in plan view. The MOS transistor TR1 is electrically isolated from each of the other semiconductor elements and the contact CT elements by the element isolation film ISL. The element isolation film ISL has, for example, a shallow trench isolation (STI) structure.

The element isolation film ISL is made of an antiferroelectric. In a state where no external electric field is applied, each of the plurality of sublattices in the crystal of the antiferroelectric has a dielectric polarization, but since two adjacent sublattices have dielectric polarizations in the opposite directions, the crystal as a whole has almost no polarization. From a different perspective, in a state where no external electric field is applied, the overall electric susceptibility X of the antiferroelectric configuring the element isolation film ISL is lower than that of a general low dielectric constant material. The element isolation film ISL is made of an antiferroelectric whose overall electric susceptibility X is less than 1. In other words, the minimum value of the relative dielectric constant of the element isolation film ISL is less than 2. Note that examples of the general low dielectric constant material include SiOCH, methyl-containing SiO₂, parylene, polyaryl ether, and others. The relative dielectric constant of these is 2.6 or more and 2.9 or less.

The material configuring the element isolation film ISL is at least one selected from the group including HfO₂, ZrO₂, Pb(In_{0.5}Nb_{0.5})O₃, NbNaO₃, ZrPbO₃, TiZrLaPbO₃, TiZrPbO₃, NH₄HPO₄, and NH₄HAsO₄.

Preferably, the antiferroelectric configuring the element isolation film ISL an amorphous a has structure or polycrystalline structure. Alternatively, the antiferroelectric configuring the element isolation film ISL may be a relaxor dielectric. In these cases, the overall electric susceptibility X of the antiferroelectric configuring the element isolation film ISL is substantially zero. Therefore, the minimum value of the relative dielectric constant of the element isolation film ISL is substantially 1.

The maximum value of the relative dielectric constant of the element isolation film ISL is greater than 2.9. Preferably, the maximum value of the relative dielectric constant of the element isolation film ISL is 4.3 or more.

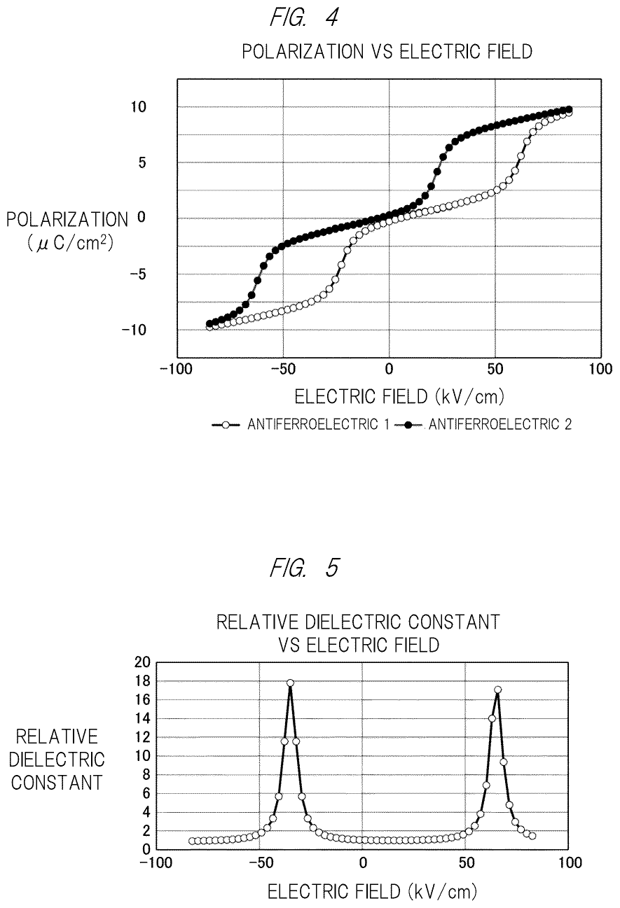

FIG. 4 is a graph illustrating a relationship between an electric field and polarization of 2-trichloromethyl benzimidazole (TCMBI) as an example of the antiferroelectric obtained by simulation. The boundary element method was used for the simulation. The white circles in FIG. 4 indicate the above relationship when the applied voltage is increased from the negative side to the positive side, and the black circles in FIG. 4 indicate the above relationship when the applied voltage is decreased from the positive side to the negative side. As illustrated in FIG. 4, the polarization-electric field curve of the antiferroelectric configuring the element isolation film ISL indicates a double hysteresis loop. As illustrated in FIG. 4, when the external electric field applied to the antiferroelectric is smaller than a specific strength, polarization occurs in the antiferroelectric in the same way as a paraelectric. When the external electric field applied to the antiferroelectric is equal to or larger than a specific strength, polarization directions of the plurality of sublattices in the antiferroelectric are aligned, and polarization spontaneously occurs (spontaneous polarization) in the antiferroelectric in the same way as a ferroelectric. In this case, the relative dielectric constant of the antiferroelectric is greater than 2.9, for example, greater than 4.0. The polarization amount (remanent polarization amount) of the antiferroelectric when the external electric field applied to the antiferroelectric is set to zero is 15 μC/cm² or less. That is, the amount of remanent polarization of the antiferroelectric is almost zero. Note that the spontaneous polarization and remanent polarization of the element isolation film ISL can be determined based on a D-E curve obtained by, for example, measuring the electric flux density D when the electric field E is applied to the element isolation film ISL.

FIG. 5 is a graph illustrating the relationship between the electric field and the relative dielectric constant when the electric field applied gradually increases, obtained by the above simulation for the example of the antiferroelectric illustrated in FIG. 4. As illustrated in FIG. 5, the relative dielectric constant of the antiferroelectric configuring the element isolation film ISL is kept less than 2 until the strength of the electric field exceeds a specific value, and becomes greater than 2.9 when the strength of the electric field exceeds the specific value. The specific value is, for example, 50 kV/cm or more and 70 kV/cm or less.

In the semiconductor device 101, during the normal operation, the electric field applied between a pair of elements via the element isolation film ISL is set to be less than the electric field at which the spontaneous polarization occurs in the antiferroelectric.

In this specification, the normal operation of a semiconductor device refers to a normal operation that is predetermined for the semiconductor device, and an operation in a state where no charge is generated due to cosmic rays, ESD (Electro-static Discharge), and the like.

The semiconductor device 101 is provided such that the voltage applied during the normal operation between two regions isolated by the element isolation film ISL is set to be less than twice the drive voltage of the MOS transistor TR1 formed in the region. When the drive voltage of the MOS transistor TR1 is 1 V, the semiconductor device 101 is provided such that the voltage applied during the normal operation between two regions isolated by the element isolation film ISL is set to be less than 2 V. When the drive voltage of the MOS transistor TR1 is 3.3 V, the semiconductor device 101 is provided such that the voltage applied during the normal operation between two regions isolated by the element isolation film ISL is set to be less than 6.6 V.

The electric field applied during the normal operation between two regions isolated by the element isolation film ISL is, for example, less than 50 kV/cm.

In the semiconductor device 101, the electric field applied to the element isolation film ISL due to cosmic rays is less than the electric field that causes the antiferroelectric configuring the element isolation film ISL to undergo a phase transition to a ferroelectric. Preferably, the electric field applied to the element isolation film ISL due to ESD is less than the electric field that causes the antiferroelectric configuring the element isolation film ISL to undergo a phase transition a to ferroelectric.

In this specification, cosmic rays refer to radiation coming from outer space or particles generated by such radiation, and have an energy on the order of several MeV to GeV. Cosmic rays are particle radiation or high-energy electromagnetic radiation. The particle radiation is, for example, alpha rays, beta rays, neutron rays, or proton rays. The electromagnetic radiation is, for example, gamma rays or X-rays. The particles generated by such radiation are, for example, neutrons generated by the collision of the cosmic rays with atomic nuclei of oxygen, nitrogen, or the like when they enter the atmosphere.

Preferably, the element isolation film ISL does not have a plurality of voids formed therein. Preferably, the element isolation film ISL does not contain a porous material. Preferably, the Young's modulus of the element isolation film ISL is higher than the Young's modulus of a low dielectric constant material made of a porous material. Preferably, the Young's modulus of the element isolation film ISL is 8 GPa or more.

The film thickness of the element isolation film ISL is 2 nm or more and less than 50 nm. The film thickness of the element isolation film ISL is the dimension of the element isolation film ISL in the Z direction.

The semiconductor device 101 further includes, for example, a plurality of wiring layers M, a plurality of interlayer insulating films ILD, and a plurality of contacts CT. The plurality of wiring layers M and the plurality of interlayer insulating films ILD are stacked in the Z direction. The plurality of wiring layers M is arranged on the upper surface of each of the plurality of interlayer insulating films ILD or in wiring trenches formed in the upper surface of each of the plurality of interlayer insulating films ILD. Each of the plurality of wiring layers M may be formed by a damascene method. Through holes are formed in the plurality of interlayer insulating films ILD. Each of the plurality of contacts CT is formed in the through holes.

The plurality of interlayer insulating films ILD includes a lower interlayer insulating film ILD1 located at the lowermost position, an upper interlayer insulating film located at the uppermost position, and at least one middle interlayer insulating film ILD3 located between the lower interlayer insulating film ILD1 and the upper interlayer insulating film.

The lower interlayer insulating film ILD1 is formed on the first surface SF1 so as to cover the gate electrode GE and the sidewall insulating film SW. The lower interlayer insulating film ILD1 is in contact with, for example, the gate electrode GE, the sidewall insulating film SW, and the element isolation film ISL. The lower interlayer insulating film ILD1 is in contact with, for example, the source SO and the drain DR. The lower interlayer insulating film ILD1 is not in contact with the gate insulating film GI.

The plurality of wiring layers M includes a lower wiring layer M1 located at the lowermost position, an upper wiring layer located at the uppermost position, and at least one middle wiring layer located between the lower wiring layer M1 and the upper wiring layer.

The lower wiring layer M1 is arranged on the upper surface of the lower interlayer insulating film ILD1 or in the trench formed in the upper surface. The lower wiring layer M1 includes a plurality of first wiring layers M1A and second wiring layers M1B that are arranged at intervals from each other in at least one of the X direction and the Y direction. Each of the plurality of first wiring layers M1A is connected to the drain DR or the source SO of the MOS transistor TR via the first contact CT layer C1A. The second wiring layer M1B is connected to the p-type well PW via the second contact CT layer C1B. The first contact CT layer C1A and the second contact CT layer C1B are formed in the through holes formed in the lower interlayer insulating film ILD1.

The upper wiring layer is formed on the upper interlayer insulating film. The upper wiring layer is configured as a pad. Each of the plurality of interlayer insulating films ILD overlaps with the pad in the Z direction.

### Method of Manufacturing Semiconductor Device

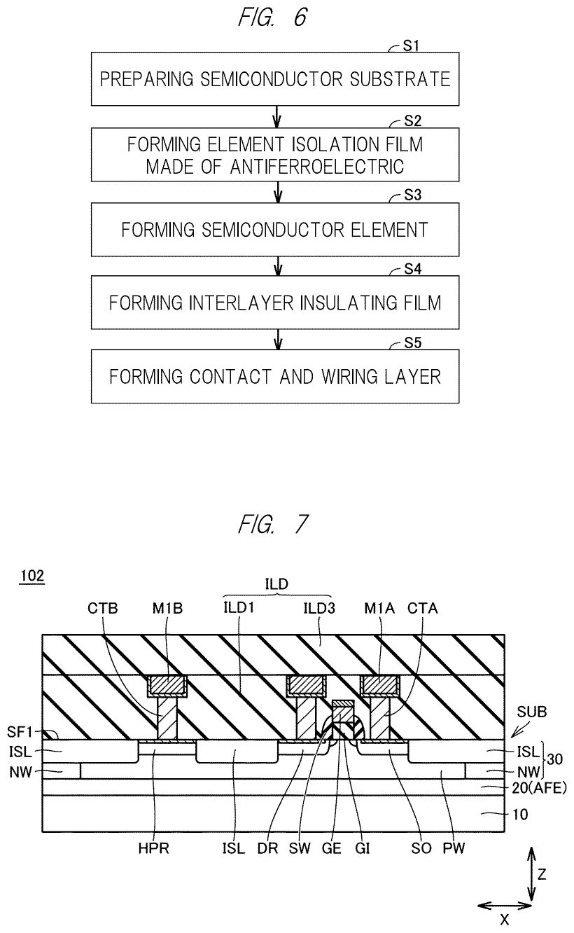

An example of a method of manufacturing the semiconductor device 101 will be described below with reference to FIG. 6.

First, the semiconductor substrate SUB is prepared (first step). The semiconductor substrate SUB has the first surface SF1. The semiconductor substrate SUB is prepared as, for example, an SOI substrate.

Second, the element isolation film ISL is formed in the single crystal layer 30 of the semiconductor substrate SUB (third step). The element film made an isolation ISL is of antiferroelectric. In this step, the element isolation film ISL is formed by heating to a temperature lower than the Curie point of the antiferroelectric. Furthermore, after this step, the element isolation film ISL is not heated to a temperature equal to or higher than the Curie point of the antiferroelectric. This prevents the antiferroelectric configuring the element isolation film ISL from transitioning to a ferroelectric.

Third, the MOS transistor TR is formed on the first surface SF1 of the semiconductor substrate SUB (second step). In this step, the contact CT element is also formed.

Fourth, the lower interlayer insulating film ILD1 is formed on the first surface SF1 so as to cover the MOS transistor TR (fourth step).

Fifth, the contact CT and the wiring layer M are formed (fifth step). The method of forming the wiring layer M1 is, for example, a damascene method. Thereafter, the middle interlayer insulating film, the middle wiring layer, the upper interlayer insulating film, the upper wiring layer, and others are formed. In this manner, the semiconductor device 101 illustrated in FIG. 2 and FIG. 3 is manufactured. In this step, post-metallization annealing (PMA) may be performed. In this case, the heating temperature is set to a temperature lower than the Curie point of the antiferroelectric configuring the lower interlayer insulating film ILD1.

In the second to fifth steps described above, the layout patterns of the elements are formed using photolithography. The layout patterns of the elements are designed and verified based on the specifications required for the semiconductor device 101. The layout patterns of the elements are designed based on the results of a circuit simulation that simulates the operation of the circuit including the MOS transistor TR or by an automatic place and route (P&R) program. One example of the circuit simulation is SPICE (Simulation Program with Integrated Circuit Emphasis).

Note that the third step described above may be performed after the step of forming the MOS transistor TR (second step).

The method of manufacturing the semiconductor device 101 may further include a step of adjusting the relative dielectric constant of the element isolation film ISL by irradiating the element isolation film ISL with electromagnetic waves after the third step described above. This step may be performed within the third step. This step may be performed as an annealing treatment for the element isolation film ISL. For example, when the element isolation film ISL is composed of an antiferroelectric having a perovskite structure, a solvent containing the antiferroelectric material is spin-coated on the first surface SF1, and then the solvent is volatilized by irradiating it with electromagnetic waves under predetermined conditions, thereby obtaining the element isolation film ISL with an adjusted dielectric constant. The electromagnetic waves may be laser light.

Note that this step may be performed as an annealing treatment using a hot plate. In this case, since the element isolation film ISL is gradually cooled after heating by the hot plate is stopped, the crystal structure of the element isolation film ISL can be made single crystal.

In addition, this step may reduce the uniformity of at least one of the film quality and film thickness of the element isolation film ISL. For example, the element isolation film ISL after this step may contain at least one of a large number of aggregates and voids. Therefore, in this step, a process for improving the uniformity of the film quality and film thickness of the element isolation film ISL may be performed before the above-described step of adjusting the relative dielectric constant. As such a process, for example, a solvent such as chlorobenzene, dimethylformamide, or 1-cyclohexyl-2-pyrrolidone may be spin-coated on a solvent containing an antiferroelectric material spin-coated on the first surface SF1.

### Effects of Semiconductor Device 101

The effects of the semiconductor device 101 will be described based on a comparison with a comparative example. The semiconductor device according to the comparative example 1 differs from the semiconductor device 101 only in that the element isolation film ISL is made of a general low dielectric constant material. As described above, the relative dielectric constant of a general low dielectric constant material is 2.6 or more and 2.9 or less. Therefore, in the semiconductor device according to the comparative example 1, the operating speed of the semiconductor element can be increased as compared with a semiconductor device having an element isolation film made of a dielectric material having a relative dielectric constant greater than 2.9. However, in the semiconductor device according to the comparative example 1, it is difficult to suppress the occurrence of soft errors caused by cosmic rays.

Cosmic rays that reach the ground from outer space include high-energy radiation or secondary neutrons that are generated when the radiation collides with and destroys the nuclei of atoms of oxygen and others in the atmosphere. The energy of these cosmic rays is several MeV to GeV, and when they enter a semiconductor device, they destroy the nuclei of the atoms configuring the semiconductor device, and ultimately generate a large amount of electric charge (hereinafter referred to as abnormal charge). The large amount of abnormal charge is not captured by the element isolation film made of a low dielectric constant material, and reaches the impurity region that constitutes the memory node in the memory circuit. In an n-type MOS transistor, the abnormal charge reaches the drain.

Specifically, when the nuclei of atoms configuring the single crystal layer 30 are destroyed by cosmic rays, a dipole composed of a proton and an electron is generated. The energy of the dipole is on the 10 MV order immediately after its generation, but attenuates as the distance between the proton and the electron increases. When the distance between the two expands to an extent of several atoms, the dipole becomes an electron-hole pair with an energy on the keV order. In the process of the electron-hole pair moving in the semiconductor device, the energy thereof weakens to the 10 eV order, but the electrons and holes are not captured by the element isolation film made of a low dielectric constant material and reach the impurity region configuring the memory node in the memory circuit MEM. As a result, the semiconductor device according to the comparative example 1 has a problem in that the data held in the memory node is inverted and soft errors are likely to occur.

Meanwhile, in the semiconductor device 101, since the element isolation film ISL is made of an antiferroelectric, the relative dielectric constant of the element isolation film ISL becomes higher than the relative dielectric constant of the element isolation film ISL during the normal operation only when the strength of the electric field applied to the element isolation film ISL exceeds the specific value mentioned above by the abnormal charge. Therefore, a part of the abnormal charge can be captured by the inter-wiring capacitance with the element isolation film ISL as the dielectric. As a result, in the semiconductor device 101, it is possible to o simultaneously achieve high integration of semiconductor elements and miniaturization of each wiring and suppression of the propagation delay and the occurrence of soft errors associated therewith.

In the semiconductor device 101, the maximum value of the relative dielectric constant of the element isolation film ISL is greater than 2.9. In other words, the maximum value of the relative dielectric constant of the element isolation film ISL is higher than the relative dielectric constant of a low dielectric constant material. In such a semiconductor device 101, the occurrence of the above-mentioned soft errors can be suppressed as compared with the semiconductor device according to the comparative example 1. Preferably, the maximum value of the relative dielectric constant of the element isolation film ISL is greater than 4.3. In other words, the maximum value of the relative dielectric constant of the element isolation film ISL is higher than the relative dielectric constant of a silicon oxide film. These semiconductor devices 101 are particularly suitable for technical fields in which high integration of semiconductor elements and suppression of the above-mentioned soft errors are simultaneously required, such as the fields of automobiles, aerospace systems, and medical equipment. In aerospace systems, even the soft errors with a very low probability of occurrence cannot be tolerated because the effect of blocking cosmic rays by atmosphere cannot be expected, and the semiconductor device 101 is suitable for such a case.

In addition, in the semiconductor device according to the comparative example 1, when the capacitance value of the element isolation film is to be reduced in order to increase the operating speed, the distance between two adjacent regions via the element isolation film must be widened. Therefore, in the semiconductor device according to the comparative example 1, it is difficult to increase the operating speed while suppressing the occurrence of soft errors.

Meanwhile, in the semiconductor device 101, the element isolation film ISL is made of an antiferroelectric. Therefore, in a state where no external electric field is applied, the overall electric susceptibility X of the antiferroelectric configuring the element isolation film is lower than the electric susceptibility of a general low dielectric constant material and is less than 1. In other words, the minimum value of the relative dielectric constant of the element isolation film is less than 2. Therefore, the capacitance between two conductors adjacent via the element isolation film (for example, the capacitance between the first wiring layer M1A and the second wiring layer M1B) in the semiconductor device 101 is smaller than the capacitance between two conductors adjacent via the element isolation film made of a general low dielectric constant material in the semiconductor device according to the comparative example 1. Therefore, the semiconductor device 101 can increase the operating speed while suppressing the occurrence of soft errors, as compared with the semiconductor device according to the comparative example 1.

Further, in the semiconductor device according to the comparative example 1, it is difficult to narrow the width of the element isolation film in the X direction or Y direction in order to suppress the decrease in the operating speed of the semiconductor element due to the increase in the capacitance value of the element isolation film. In other words, in the semiconductor device according to the comparative example 1, it is difficult to reduce the chip area while suppressing the decrease in the operating speed of the semiconductor element. Meanwhile, in the semiconductor device 101, the element isolation film is made of an antiferroelectric, and the minimum value of the relative dielectric constant of the antiferroelectric is less than 2. Therefore, in the semiconductor device 101, even when the width of the element isolation film in the X-direction or Y-direction is narrowed, the increase in the capacitance value of the element isolation film can be suppressed as compared with the semiconductor device according to the comparative example 1. As a result, in the semiconductor device 101, it is possible to reduce the chip area while suppressing the decrease in the operating speed of the semiconductor element.

Note that the size and spacing of the semiconductor elements in the semiconductor device 101 may be the same as those of the semiconductor device according to the comparative example 1, and in this case, the operating speed can be increased as compared with the semiconductor device according to the comparative example 1.

Furthermore, in the semiconductor device 101, since the remanent polarization of the antiferroelectric configuring the element isolation film ISL is 15 μC/cm² or less, abnormal charge is unlikely to remain.

In the semiconductor device 101, the film thickness of the element isolation film ISL is 2 nm or more and 50 nm or less. When the element isolation film ISL and an element isolation film made of a general low dielectric constant material having the same film thickness are compared, the minimum value of the relative dielectric constant of the element isolation film ISL is lower than the relative dielectric constant of the general low dielectric constant Therefore, material. Therefore, in the semiconductor device 101, if the film thickness of the element isolation film ISL is the same as that of the element isolation film of the semiconductor device according to the comparative example 1, the capacitance value of the element isolation film ISL during the normal operation can be made smaller than that of the element isolation film made of a general low dielectric constant material. On the other hand, in the semiconductor device 101, if the capacitance value of the element isolation film ISL during the normal operation is the same as that of the element isolation film of the semiconductor device according to the comparative example 1, the film thickness of the element isolation film ISL can be made larger than that of an element isolation film made of a general low dielectric constant material. As a result, in the semiconductor device 101, the leakage current can be reduced while reducing the capacitance of the element isolation film as compared with the semiconductor device according to the comparative example 1, so that higher performance can be achieved.

In the semiconductor device 101, the electric field applied between a pair of elements adjacent via the element isolation film ISL during the normal operation is set to be less than the electric field at which spontaneous polarization occurs in the antiferroelectric, and thus the relative dielectric constant of the element isolation film ISL can be maintained at less than 2 during the normal operation. For example, the electric field applied between a pair of elements during the normal operation may be less than 50 kV/cm. The electric field at which spontaneous polarization occurs in the antiferroelectric may be 50 kV/cm or more.

Furthermore, in the semiconductor device 101, the external electric field applied to the element isolation film ISL due to cosmic rays is set to be less than the electric field that causes the antiferroelectric configuring the element isolation film ISL to undergo a phase transition to a ferroelectric. Therefore, after the application of the external electric field is stopped, the relative dielectric constant of the element isolation film ISL becomes less than 2 again, and the abnormal charge is gradually released from the element isolation film ISL. As a result, in the semiconductor device 101, even when the external electric field is repeatedly applied at intervals, the occurrence of the soft error can be suppressed each time, and further, the propagation delay can be suppressed during the normal operation after the external electric field is removed.

Note that an external electric field equal to or larger than the electric field that causes the antiferroelectric configuring the element isolation film ISL to undergo a phase transition to a ferroelectric may be applied to the element isolation film ISL. The element isolation film ISL may transition from an antiferroelectric to a ferroelectric. In this case, the above-mentioned effect of the element isolation film ISL can be reproduced in the semiconductor device 101 by performing a process for returning the element isolation film ISL from a ferroelectric to an antiferroelectric. As a process for returning the element isolation film ISL from a ferroelectric to an antiferroelectric, for example, a process of alternately applying positive and negative voltages such as an AC voltage to the element isolation film ISL and gradually decreasing the voltage can be presented. By this process, the crystal structure of the ferroelectric can be disturbed and the crystal structure of the antiferroelectric can be reproduced. As another example of the process, a process of heating the element isolation film ISL and then rapidly cooling it can be presented. By this process, the crystal structure of the ferroelectric can be destroyed and the crystal structure of the antiferroelectric can be reproduced.

In addition, in the semiconductor device according to the comparative example 1, when the abnormal charge due to ESD enters from the pad, the element isolation film made of a low dielectric constant material cannot capture the abnormal charge.

Meanwhile, in the semiconductor device 101, when the abnormal charge due to ESD enters from the pad, an external electric field of 50 kV/cm or more is applied to the element isolation film ISL located between the pad and the semiconductor element. As a result, the relative dielectric constant of the element isolation film ISL becomes higher than the relative dielectric constant of the low dielectric constant material, and a part of the abnormal charge can be captured by the inter-wiring capacitance with the element isolation film ISL as the dielectric. This makes it possible to reduce the current value excited by ESD, and to suppress the current excited by ESD to be less than the threshold of the current that destroys the semiconductor element. As a result, in the semiconductor device 101, it is possible to suppress the destruction of the semiconductor element due to ESD.

In the method of manufacturing the semiconductor device 101, in the step of forming the element isolation film ISL, the temperature of the element isolation film ISL is set to be lower than the Curie point of the antiferroelectric configuring the element isolation film ISL, and it is thus possible to suppress the antiferroelectric configuring the element isolation film ISL from transitioning to a ferroelectric.

### Second Embodiment

Unless otherwise specified, a semiconductor device 102 according to a second embodiment has the same configuration, operating principle, and effects as those of the above-mentioned first embodiment. Therefore, the description of the same configuration, operating principle, and effects as those of the above-mentioned first embodiment is not repeated.

As illustrated in FIG. 7, the semiconductor device 102 according to the second embodiment differs from the semiconductor device 101 in that the substrate isolation film 20 is made of an antiferroelectric instead of the element isolation film ISL. The antiferroelectric configuring the substrate isolation film 20 may be the same as the antiferroelectric configuring the element isolation film ISL in the semiconductor device 101.

The semiconductor device 102 is provided such that the voltage applied during the normal operation between the bulk layer 10 and the single crystal layer 30 isolated by the substrate isolation film 20 is set to be less than twice the drive voltage of the MOS transistor TR1 formed in the region. When the drive voltage of the MOS transistor TR1 is 1 V, the semiconductor device 102 is provided such that the voltage applied during the normal operation between the two regions isolated by the substrate isolation film 20 is set to be less than 2 V. When the drive voltage of the MOS transistor TR1 is 3.3 V, the semiconductor device 102 is provided such that the voltage applied during the normal operation between the two regions isolated by the substrate isolation film 20 is set to be less than 6.6 V.

The electric field applied during the normal operation between the two regions isolated by the substrate isolation film 20 is, for example, less than 50 kV/cm.

### Method of Manufacturing Semiconductor Device 102

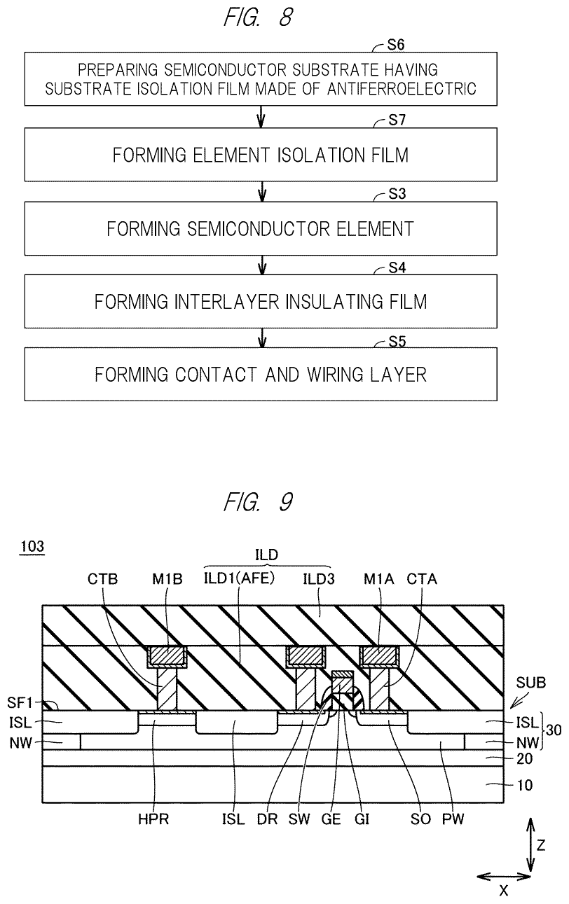

The method of manufacturing the semiconductor device 102 is basically the same as that of the semiconductor device 101. Hereinafter, the differences of the method of manufacturing the semiconductor device 102 from the method of manufacturing the semiconductor device 101 will be mainly described with reference to FIG. 8.

First, the semiconductor substrate SUB having the substrate isolation film 20 made of an antiferroelectric is prepared (sixth step). The semiconductor substrate SUB has the first surface SF1. The substrate isolation film 20 is formed by heating to a temperature lower than the Curie point of the antiferroelectric. Furthermore, after this step, the substrate isolation film 20 is not heated to a temperature equal to or higher than the Curie point of the antiferroelectric. This prevents the antiferroelectric configuring the substrate isolation film 20 from transitioning to a ferroelectric.

Second, the element isolation film ISL is formed in the single crystal layer 30 of the semiconductor substrate SUB (seventh step).

Third, the MOS transistor TR is formed on the first surface SF1 of the semiconductor substrate SUB (third step). In this step, the contact CT element is also formed.

Fourth, the lower interlayer insulating film ILD1 is formed on the first surface SF1 so as to cover the MOS transistor TR (fourth step).

Fifth, the contact CT and the wiring layer M are formed (fifth step). The method of forming the wiring layer M1 is, for example, a damascene method. Thereafter, the middle interlayer insulating film, the middle wiring layer, the upper interlayer insulating film, the upper wiring layer, and others are formed. In this manner, the semiconductor device 102 illustrated in FIG. 7 is manufactured. In this step, post-metallization annealing (PMA) may be performed. In this case, the heating temperature is set to a temperature lower than the Curie point of the antiferroelectric configuring the substrate isolation film 20.

Note that the seventh step described above may be performed after the step of forming the MOS transistor TR (second step).

The method of manufacturing the semiconductor device 102 may further include a step of adjusting the relative dielectric constant of the substrate isolation film 20 by irradiating the substrate isolation film 20 with electromagnetic waves during the first step or after the first step. This step may be performed in the same manner as the step of adjusting the relative dielectric constant of the element isolation film ISL in the method of manufacturing the semiconductor device 101. This step may be performed as an annealing treatment for the substrate isolation film 20. For example, when the substrate isolation film 20 is composed of an antiferroelectric having a perovskite structure, a solvent containing the antiferroelectric material is spin-coated on the first surface SF1, and then the solvent is volatilized by irradiating it with electromagnetic waves under predetermined conditions, thereby obtaining the substrate isolation film 20 with an adjusted dielectric constant. The electromagnetic waves may be laser light.

Note that this step may be performed as an annealing treatment using a hot plate. In this case, since the substrate isolation film 20 is gradually cooled after heating by the hot stopped, the crystal structure of the substrate plate is isolation film 20 can be made single crystal.

In addition, this step may reduce the uniformity of at least one of the film quality and film thickness of the substrate isolation film 20. For example, the substrate isolation film 20 after this step may contain at least one of a large number of aggregates and voids. Therefore, in this step, a process for improving the uniformity of the film quality and film thickness of the substrate isolation film 20 may be performed before the above-described step of adjusting the relative dielectric constant. As such a process, for example, a solvent such as chlorobenzene, dimethylformamide, or 1-cyclohexyl-2-pyrrolidone may be spin-coated on a solvent containing an antiferroelectric material spin-coated on the first surface SF1.

### Effects of Semiconductor Device 102

The effects of the semiconductor device 102 will be described based on a comparison with a comparative example. The semiconductor device according to the comparative example 2 differs from the semiconductor device 102 only in that the substrate isolation film is made of a general low dielectric constant material. As described above, the relative dielectric constant of a general low dielectric constant material is 2.6 or more and 2.9 or less. Therefore, in the semiconductor device according to the comparative example 2, the operating speed of the semiconductor element can be increased as compared with a semiconductor device having a substrate isolation film made of a dielectric material having a relative dielectric constant greater than 2.9. However, in the semiconductor device according to the comparative example 2, when cosmic rays enter the single crystal layer 30 immediately below the gate insulating film GI, a large number of electron-hole pairs are generated in the single crystal layer 30 immediately below the gate insulating film GI, resulting in the conduction between the source and drain. As a result, in the semiconductor device according to the comparative example 2, it is difficult to suppress the occurrence of soft errors caused by cosmic rays while suppressing the decrease in the operating speed of the semiconductor element.

Meanwhile, in the semiconductor device 102, since the substrate isolation film 20 is made of an antiferroelectric, the relative dielectric constant of the substrate isolation film 20 becomes higher than the relative dielectric constant of the substrate isolation film 20 during the normal operation only when the strength of the electric field applied to the substrate isolation film 20 by the abnormal charge exceeds the specific value mentioned above. Therefore, a part of the abnormal charge can be captured by the substrate isolation film 20. As a result, in the semiconductor device 102, it is possible to suppress the occurrence of soft errors while suppressing the decrease in the operating speed of the semiconductor element.

### Third Embodiment

Unless otherwise specified, a semiconductor device 103 according to a third embodiment has the same configuration, operating principle, and effects as those of the above-mentioned first embodiment. Therefore, the description of the same configuration, operating principle, and effects as those of the above-mentioned first embodiment is not repeated.

As illustrated in FIG. 9, the semiconductor device 103 according to the third embodiment differs from the semiconductor device 101 in that at least one of the plurality of interlayer insulating films ILD is made of an antiferroelectric. The antiferroelectric configuring at least one of the plurality of interlayer insulating films ILD may be the same as the antiferroelectric configuring the element isolation film ISL in the semiconductor device 101. In the semiconductor device 103 illustrated in FIG. 9, only the lower interlayer insulating film ILD1 located at the lowermost position of the plurality of interlayer insulating films ILD is made of an antiferroelectric.

In the semiconductor device 103, during the normal operation, the electric field applied between a pair of conductors via at least one interlayer insulating film ILD made of an antiferroelectric is set to be less than the electric field at which spontaneous polarization occurs in the antiferroelectric.

In the semiconductor device 103, the electric field applied to the interlayer insulating film ILD due to cosmic rays is set to be less than the electric field that causes the antiferroelectric to undergo a phase transition to a ferroelectric. Preferably, the electric field applied to the interlayer insulating film ILD due to ESD is set to be less than the electric field that causes the antiferroelectric to undergo a phase transition to a ferroelectric.

The at least one interlayer insulating film ILD made of an antiferroelectric does not have a plurality of voids formed therein. The plurality of interlayer insulating films ILD does not contain a porous material. The Young's modulus of the at least one interlayer insulating film ILD made of an antiferroelectric is higher than the Young's modulus of a low dielectric constant material made of a porous material. The Young's modulus of the at least one interlayer insulating film ILD made of an antiferroelectric is 8 GPa or more.

Preferably, at least one interlayer insulating film ILD made of an antiferroelectric has an amorphous structure or a polycrystalline structure. The mechanical strength of an antiferroelectric having an amorphous structure is expected to be higher than that of an antiferroelectric having a single crystal structure. In an antiferroelectric having a polycrystalline structure, it is preferable that each of the plurality of single crystals is bonded without using a binder. The mechanical strength of such an antiferroelectric is also expected to be higher than that of an antiferroelectric having a single crystal structure.

### Effects of Semiconductor Device 103

The effects of the semiconductor device 103 will be described based on a comparison with a comparative example. The semiconductor device according to the comparative example 3 differs from the semiconductor device 103 only in that the interlayer insulating film is made of a general low dielectric constant material. As described above, the relative dielectric constant of a general low dielectric constant material is 2.6 or more. Therefore, in the semiconductor device according to the comparative example 3, it is necessary to reduce the capacitance value between two conductors by increasing the distance between the two conductors adjacent via the interlayer insulating film in order to suppress the propagation delay. Therefore, in the semiconductor device according to the comparative example 3, it is difficult to simultaneously achieve high integration of semiconductor elements and miniaturization of each wiring and suppression of the propagation delay associated therewith.

Meanwhile, in the semiconductor device 103, the lower interlayer insulating film ILD1 is made of an antiferroelectric. Therefore, in a state where no external electric field is applied, the overall electric susceptibility X of the antiferroelectric configuring the lower interlayer insulating film ILD1 is lower than the electric susceptibility of a general low dielectric constant material and is less than 1. In other words, the minimum value of the relative dielectric constant of the lower interlayer insulating film ILD1 is less than 2. Therefore, the capacitance between two conductors adjacent via the lower interlayer insulating film ILD1 (for example, the capacitance between the first wiring layer M1A and the second wiring layer M1B) in the semiconductor device 103 is smaller than the capacitance between two conductors adjacent via the interlayer insulating film ILD made of a general low dielectric constant material in the semiconductor device according to the comparative example 3. Therefore, the semiconductor device 103 can achieve high integration of semiconductor elements and miniaturization of each wiring and suppression of the propagation delay associated therewith as compared with the semiconductor device according to the comparative example 3.

The size and spacing of the semiconductor elements and wirings in the semiconductor device 103 may be the same as those of the semiconductor device according to the comparative example 3, and in this case, the operating speed can be increased as compared with the semiconductor device according to the comparative example 3.

In addition, in the semiconductor device according to the comparative example 3, when the abnormal charge due to ESD enters from the pad, the interlayer insulating film made of a low dielectric constant material cannot capture the abnormal charge. Meanwhile, in the semiconductor device 103, when ESD pulse enters from the pad, an external electric field of 50 kV/cm or more is applied to the lower interlayer insulating film ILD1 located between the pad and the semiconductor element. As a result, the relative dielectric constant of the lower interlayer insulating film ILD1 becomes higher than the relative dielectric constant of the low dielectric constant material, and a part of the abnormal charge due to ESD can be captured by the inter-wiring capacitance with the lower interlayer insulating film ILD1 as the dielectric.

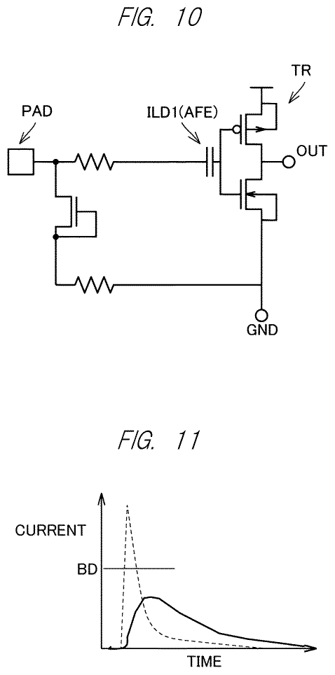

FIG. 10 is a circuit diagram illustrating an example of a circuit included in the semiconductor device 103 that is realized only when ESD pulse enters from the pad. FIG. 11 is a graph illustrating a temporal change of current flowing through a MOS transistor after the ESD pulse enters the semiconductor device. The solid line in FIG. 11 indicates the temporal change of the current flowing through the MOS transistor TR in the semiconductor device 103, and the dashed line indicates the temporal change of the current flowing through the MOS transistor in the semiconductor device according to the comparative example 3. As illustrated in FIG. 10, the lower interlayer insulating film ILD1 can function as a capacitor that suppresses a part of the abnormal charge due to ESD from reaching the MOS transistor TR. As a result, as illustrated in FIG. 11, in the semiconductor device 103, the current value flowing through the MOS transistor TR can be suppressed to be less than the current threshold BD at which the MOS transistor TR is destroyed. As a result, in the semiconductor device 103, the destruction of the semiconductor element due to ESD can be suppressed.

Also, in the semiconductor device according to the comparative example 3, it is possible to reduce the relative dielectric constant of the interlayer insulating film by using a low dielectric constant material into which a plurality of voids is introduced as the interlayer insulating film. However, when the interlayer insulating film is made of a porous low dielectric constant material, there is a problem that the mechanical strength of the interlayer insulating film is low and failures such as cracks are likely to occur in the interlayer insulating film when the wiring layer M is formed by a damascene method or the like. Such failures may cause hard errors in the semiconductor device.

Meanwhile, a plurality of voids is not formed in the interlayer insulating film ILD of the semiconductor device 103. The Young's modulus of the interlayer insulating film ILD is 8 GPa or more, and is higher than the Young's modulus of a porous low dielectric material. Therefore, constant in the semiconductor device 103, failures such as cracks and dents are unlikely to occur in the interlayer insulating film ILD. For example, when a wire is bonded to a pad by a wire bonding method, loads and ultrasonic waves are applied to each of the plurality of interlayer insulating films ILD. When such loads and ultrasonic waves are applied to an interlayer insulating film made of a porous low dielectric constant material, failures such as cracks are likely to occur. In the semiconductor device 103, even when such loads and ultrasonic waves are applied to the interlayer insulating film ILD, cracks are unlikely to occur. Also, when the wiring layer M is formed by the damascene method, a dent occurs in the interlayer insulating film when forming a wiring trench in the interlayer insulating film made of a porous low dielectric constant material, and it is thus difficult to properly form the wiring trench. In the semiconductor device 103, even when the wiring layer M1 is formed by the damascene method, a dent is unlikely to occur in the interlayer insulating film ILD. Therefore, the occurrence of hard errors can also be suppressed in the semiconductor device 103.

As illustrated in FIG. 12, in a semiconductor device 104, only the upper interlayer insulating film ILD2 of the plurality of interlayer insulating films ILD may be made of an antiferroelectric. The lower interlayer insulating film ILD1 may be made of a paraelectric or the above-mentioned general low dielectric constant material.

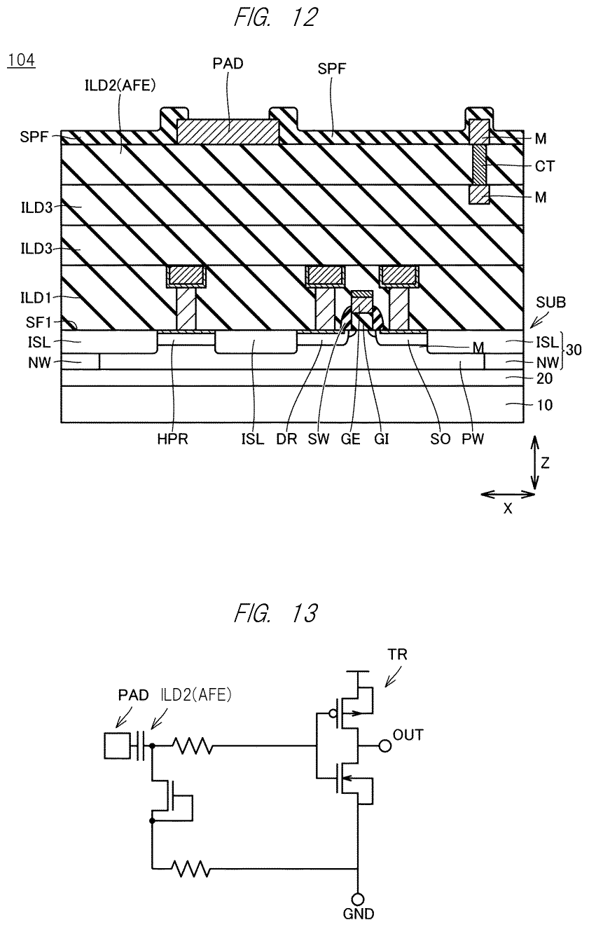

FIG. 13 is a circuit diagram illustrating an example of a circuit that is realized only when ESD pulse enters from a pad in the semiconductor device 104 illustrated in FIG. 12. As illustrated in FIG. 13, the upper interlayer insulating film ILD2 is arranged immediately below the pad PAD, and can function as a capacitor that suppresses a part of the abnormal charge due to ESD from reaching the MOS transistor TR and other electronic components. Therefore, in the semiconductor device 104 having insulating film ILD2 made an the upper interlayer of antiferroelectric, the protection ability against ESD by the antiferroelectric is higher than that of the semiconductor device 103 in which only the lower interlayer insulating film ILD1 is made of an antiferroelectric.

In the semiconductor devices 103 and 104, each of the plurality of interlayer insulating films ILD may be made of an The antiferroelectric configuring each of antiferroelectric. the plurality of interlayer insulating films ILD may be the same as or different from each other.

Note that the semiconductor devices 103 and 104 may have the same configuration as the semiconductor device 102 except that the interlayer insulating film is made of an antiferroelectric.

As described for the semiconductor device 101, the interlayer insulating film, element isolation film, and substrate isolation film made of an antiferroelectric may transition from an antiferroelectric to a ferroelectric in the semiconductor devices 102 to 104 as well. In this case, the above-mentioned effect achieved by the interlayer insulating film, element isolation film, and substrate isolation film made of an antiferroelectric in the semiconductor devices 101 to 104 can be reproduced by performing a process for returning the interlayer insulating film, element isolation film, and substrate isolation film from a ferroelectric to an antiferroelectric. As a process for returning the interlayer insulating film, element isolation film, and substrate isolation film from a ferroelectric to an antiferroelectric, a process of alternately applying positive and negative voltages such as an AC voltage to the element isolation film and the substrate isolation film and gradually decreasing the voltage can be presented as described above. By this process, the crystal structure of the ferroelectric can be disturbed and the crystal structure of the antiferroelectric can be reproduced. As another example of the process, a process of heating the element isolation film and the substrate isolation film and then rapidly cooling them can be presented. By this process, the crystal structure of the ferroelectric can be destroyed and the crystal structure of the antiferroelectric can be reproduced.

In the foregoing, the invention made by the inventor of the present invention has been specifically described above based on embodiments, but it goes without saying that the present invention is not limited to the above-described embodiments and various modifications can be made within the range not departing from the gist of the present invention.

What is claimed is:

1. A semiconductor device comprising:
a semiconductor substrate including a single crystal layer;
a plurality of semiconductor elements formed on the single crystal layer; and
an isolation film which is formed in the semiconductor substrate so as to surround each of the plurality of semiconductor elements in plan view and isolates the plurality of semiconductor elements from one another,
wherein the isolation film is made of an antiferroelectric, and
wherein a minimum value of a relative dielectric constant of the isolation film is less than 2.

2. A semiconductor device comprising:
a semiconductor substrate including a bulk layer and a single crystal layer; and
a plurality of semiconductor elements formed on the single crystal layer,
wherein the semiconductor substrate further includes an isolation film which is arranged between the bulk layer and the single crystal layer and isolates the bulk layer and the plurality of semiconductor elements from each other,
wherein the isolation film is made of an antiferroelectric, and
wherein a minimum value of a relative dielectric constant of the isolation film is less than 2.

3. The semiconductor device according to claim 1,
wherein a maximum value of the relative dielectric constant of the isolation film is greater than 2.9.

4. The semiconductor device according to claim 1,
wherein a Young's modulus of the isolation film is 8 GPa or more.

5. The semiconductor device according to claim 1,
wherein a remanent polarization amount of the isolation film is 15 μC/cm² or less.

6. The semiconductor device according to claim 1,
wherein a plurality of voids is not formed in the isolation film.

7. The semiconductor device according to claim 1,
wherein a material configuring the antiferroelectric is at one least selected group from a including HfO₂, ZrO₂, Pb(In_{0.5}Nb_{0.5})O₃, NbNaO₃, ZrPbO₃, TiZrLaPbO₃, TiZrPbO₃, NH₄H₂PO₄, and NH₄H₂AsO₄.

8. The semiconductor device according to claim 1,
wherein a thickness of the isolation film is 2 nm or more and 50 nm or less.

9. The semiconductor device according to claim 1,
wherein the isolation film is an insulating film configured to electrically insulate two regions adjacent via the isolation film from each other, and
wherein an electric field applied between the two regions during a normal operation is set to be less than an electric field at which spontaneous polarization occurs in the antiferroelectric.

10. The semiconductor device according to claim 9,
wherein a voltage applied during the normal operation between the two regions via the isolation film is less than twice a drive voltage of each of the plurality of semiconductor elements.

11. The semiconductor device according to claim 1,
wherein spontaneous polarization occurs in the antiferroelectric when cosmic rays enter.

12. The semiconductor device according to claim 11,
wherein the cosmic rays include particle radiation or high-energy electromagnetic radiation,
wherein the particle radiation includes at least one selected from a group including α rays, β rays, neutron rays, and proton rays, and
wherein the high-energy electromagnetic radiation includes at least one of γ rays or X-rays.

13. The semiconductor device according to claim 1, further comprising a first interlayer insulating film formed on the semiconductor substrate,
wherein the first interlayer insulating film is made of an antiferroelectric, and
wherein a minimum value of a relative dielectric constant of the first interlayer insulating film is less than 2.

14. The semiconductor device according to claim 13, further comprising a pad arranged on the first interlayer insulating film,
wherein spontaneous polarization occurs in the antiferroelectric when an electric field of 50 kV/cm or more is applied to the pad.

15. The semiconductor device according to claim 14,
wherein a polarization amount of the first interlayer insulating film is reduced to 15 μC/cm² or less after the application of the electric field is stopped.

16. The semiconductor device according to claim 13, further comprising a second interlayer insulating film formed between the semiconductor substrate and the first interlayer insulating film,
wherein the second interlayer insulating film is made of a paraelectric.

17. The semiconductor device according to claim 14,
wherein the first interlayer insulating film has a second surface,
wherein the pad is formed on the second surface, and
wherein the antiferroelectric configuring the second surface of the first interlayer insulating film has an amorphous structure or a polycrystalline structure.

18. The semiconductor device according to claim 1, further comprising:
a gate electrode formed on the single crystal layer via a gate insulating film;
a sidewall insulating film formed so as to cover side surfaces of each of the gate insulating film and the gate electrode; and
an interlayer insulating film formed on the single crystal layer so as to cover the gate electrode and the sidewall insulating film,
wherein the interlayer insulating film is made of an antiferroelectric, and
wherein the interlayer insulating film is arranged at an interval from the gate insulating film.

19. The semiconductor device according to claim 18,
wherein the interlayer insulating film is in contact with the sidewall insulating film.

20. A method of manufacturing a semiconductor device comprising:
a first step of preparing a semiconductor substrate including a single crystal layer;
a second step of forming a plurality of semiconductor elements on the single crystal layer; and
a third step of forming an isolation film which isolates the plurality of semiconductor elements from one another in the single crystal layer,
wherein, in the third step, the isolation film made of an antiferroelectric is formed by heating to a temperature lower than a Curie point of the antiferroelectric so as to surround each of the plurality of semiconductor elements in plan view.

21. A method of manufacturing a semiconductor device comprising:
a first step of preparing a semiconductor substrate including a bulk layer, a single crystal layer, and an isolation film which is arranged between the bulk layer and the single crystal layer and isolates the bulk layer and the single crystal layer from each other; and
a second step of forming a plurality of semiconductor elements on the single crystal layer,
wherein, in the first step, the isolation film made of an antiferroelectric is formed by heating to a temperature lower than a Curie point of the antiferroelectric.

22. The method of manufacturing the semiconductor device according to claim 20, further comprising a step of designing a layout of the isolation film based on a result of a circuit simulation that simulates an operation of a circuit including the plurality of semiconductor elements,
wherein the isolation film is formed based on the layout.
